(19) United States
(12) Patent Application Publication
(10) Pub. No.: US 2012/0292099 A1
(43) Pub. Date: Nov. 22, 2012

(54) ELECTRONIC DEVICE CASING AND DISASSEMBLING METHOD THEREOF

(75) Inventors: Yi-Ming Chang, Taipei City (TW); Ping-Hsien Niu, Taipei City (TW)

(73) Assignee: COMPAL ELECTRONICS, INC., Taipei City (TW)

(21) Appl. No.: 13/473,618

(22) Filed: May 17, 2012

Related U.S. Application Data
(60) Provisional application No. 61/487,252, filed on May 17, 2011.

(51) Int. Cl. H05K 7/14; B23P 11/00

(52) U.S. Cl. 174/535; 29/426.1

(57) ABSTRACT

The invention provides an electronic device casing, which includes a first shell, a second shell, at least one elastic element and at least one magnetic element. The first shell has a first engage portion. The second shell is disposed at a side of the first shell. The elastic element is disposed between the magnetic element and the second shell, and the magnetic element is pushed towards the first engage portion under an elastic force of the elastic element so as to prevent the second shell separating from the first shell. In addition, a disassembling method of the electronic device casing is also provided.

### CROSS-REFERENCE TO RELATED APPLICATION

This application claims the priority benefit of U.S. provisional application Ser. No. 61/487,252, filed May 17, 2011. The entirety of the above-mentioned patent application is hereby incorporated by reference herein and made a part of this specification.

### BACKGROUND OF THE INVENTION

1. Field of the Invention

The invention generally relates to a casing and a disassembling method thereof, and more particularly, to an electronic device casing and a disassembling method thereof.

2. Description of Related Art

Currently, in the era of information explosion, electronic products have become indispensable in daily life. As the continuous progress of the electronic technology, electronic products with humanization designs and preferred functions are bringing out the new products all the time, such as tablet computers, which has gradually become an indispensable tool in daily life due to the convenience and portability.

In general, the tablet computer chassis are at most composed of a top cover and a lower cover, and both the top cover and the lower cover have plastic hooks for assembling the top cover and the lower cover through the hooking between the plastic hooks. In addition, some of the tablet computers have metallic springs disposed on the top cover by punching process so as to assembling the top cover and the lower cover through the hooking between the metallic springs and the lower cover. However, whether it is assembled by plastic hooks or metallic springs, the conventional methods make the top cover of a tablet computer hard to be detached from the lower cover, which leads to maintenance difficulty.

### SUMMARY OF THE INVENTION

Accordingly, the invention is directed to an electronic device casing and a disassembling method thereof facilitating to detach the electronic device casing.

The invention provides an electronic device casing, which includes a first shell, a second shell, at least one elastic element and at least one magnetic element. The first shell has a first engage portion. The second shell is disposed at a side of the first shell. The elastic element is disposed between the magnetic element and the second shell, and the magnetic element is pushed towards the first engage portion under an elastic force of the elastic element so as to prevent the second shell separating from the first shell.

In an embodiment of the present invention, the above-mentioned magnetic element respectively has an N-pole magnetic end and an S-pole magnetic end, and the magnetic element connects the elastic element by the N-pole magnetic end.

In an embodiment of the present invention, the above-mentioned magnetic element respectively has an N-pole magnetic end and an S-pole magnetic end, and the magnetic element connects the elastic element by the S-pole magnetic end.

In an embodiment of the present invention, the above-mentioned first engage portion is a fillister.

In an embodiment of the present invention, the above-mentioned second shell has a second engage portion, and the second engage portion and the first engage portion are leant against each other.

In an embodiment of the present invention, the above-mentioned electronic device casing further includes at least one base, in which the base is disposed at the second shell and the elastic element is disposed at the base.

In an embodiment of the present invention, the quantity of the above-mentioned at least one magnetic element is plural, the quantity of the at least one elastic element is plural, each of the magnetic elements has an N-pole magnetic end and an S-pole magnetic end, parts of the magnetic elements respectively connect the corresponding elastic elements by the N-pole magnetic ends, and parts of the magnetic elements respectively connect the corresponding elastic elements by the S-pole magnetic ends.

In an embodiment of the present invention, the above-mentioned magnetic elements are arranged in a sequence of polarities.

The invention further provides a disassembling method of electronic device casing, which is suitable for the above-mentioned electronic device casing and includes: first, providing a disassembling fixture having a magnetic portion; next, placing the electronic device casing at the disassembling fixture so as to withstand the elastic force of the elastic element by the magnetic repulsion between the magnetic element and the magnetic portion, such that the magnetic element moves away from the first engage portion; further, separating the second shell from the first shell.

Based on the description above, in the electronic device casing of the invention, the magnetic element is pushed towards the first engage portion of the first shell through the elastic force of the elastic element so as to prevent the second shell separating from the first shell. When a user places the electronic device casing at a disassembling fixture with a magnetic portion, the magnetic repulsion between the magnetic element and the magnetic portion makes the magnetic element move away from the first engage portion, such that the second shell is able to be separated from the first shell. In this way, the invention makes detaching the electronic device casing more convenient.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a partial three-dimensional diagram of an electronic device casing according to an embodiment of the invention.

FIG. 2 is a flowchart of a disassembling method of the electronic device casing of FIG. 1.

FIGS. 3A-3C are diagrams showing the disassembling steps of the electronic device casing of FIG. 1.

FIG. 4 is a three-dimensional diagram of partial parts of the electronic device casing of FIG. 1.

FIGS. 5A and 5B are diagrams showing the assembling step of the base and the second shell in FIG. 1.

FIG. 6A is a three-dimensional diagram of the electronic device casing of the electronic device casing of FIG. 1.

FIG. 6B is a three-dimensional diagram of the disassembling fixture of FIG. 3A.

FIG. 6C is a three-dimensional diagram showing placing the electronic device casing of FIG. 6A at the disassembling fixture of FIG. 6B.

FIG. 7A is a partial top view diagram of the electronic device casing of FIG. 6A.

FIG. 7B is a partial top view diagram of the disassembling fixture of FIG. 6B.

FIG. 7C is a partial top view diagram of the electronic device casing and the disassembling fixture in FIG. 6C.

### DESCRIPTION OF THE EMBODIMENTS

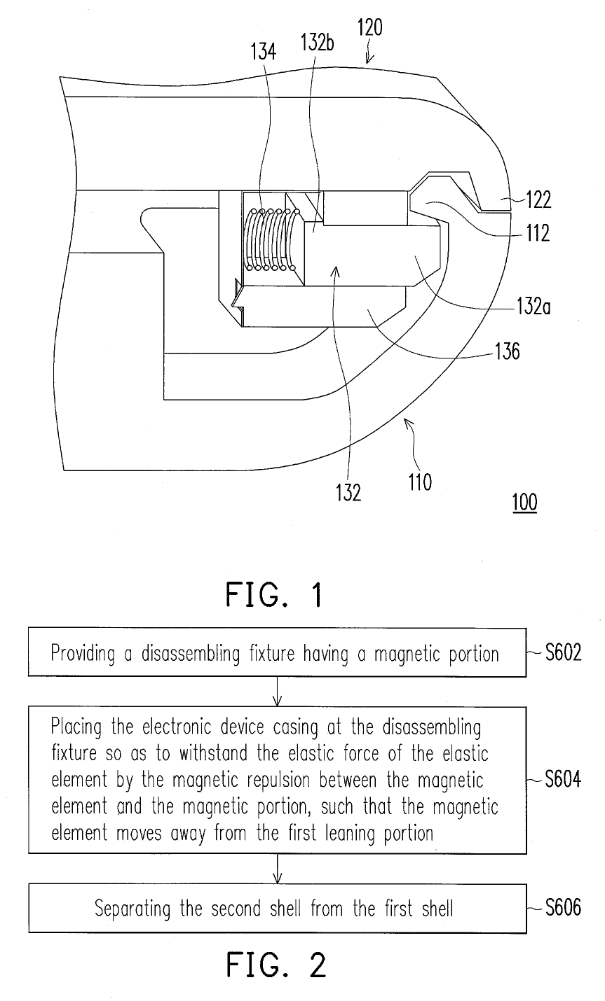

FIG. 1 is a partial three-dimensional diagram of an electronic device casing according to an embodiment of the invention. Referring to FIG. 1, an electronic device casing 100 of the embodiment includes a first shell 110, a second shell 120, at least one elastic element 134 and at least one magnetic element 132. The first shell 110 has a first engage portion 112. The second shell 120 is disposed at a side of the first shell 110. The elastic element 134 is, for example, a compression spring and disposed between the second shell 120 and the magnetic element 132. The magnetic element 132 is pushed towards the first engage portion 112 under the elastic force of the elastic element 134 to prevent the second shell 120 from separating from the first shell 110.

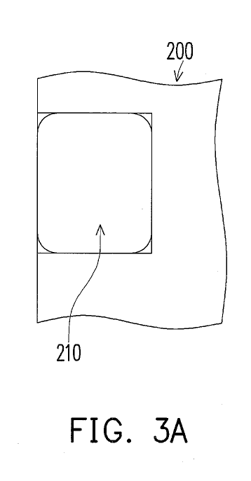

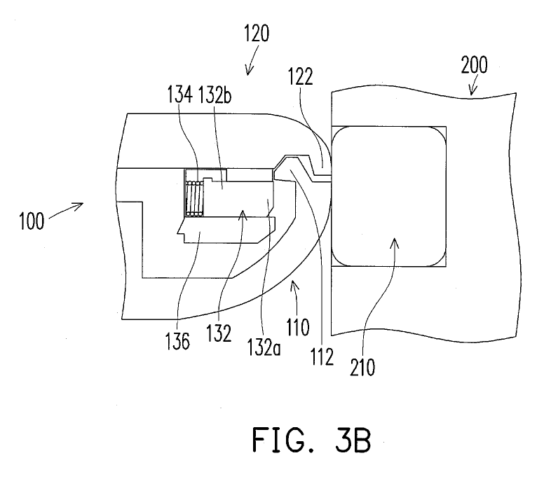

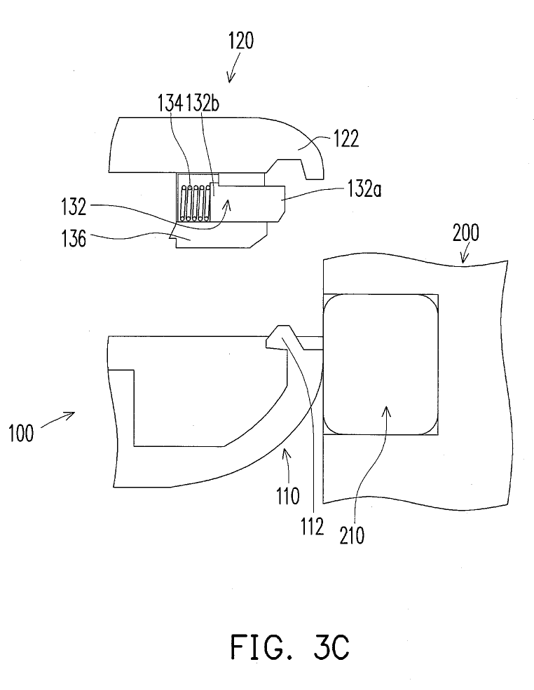

The disassembling flowchart of the electronic device casing 100 of FIG. 1 is described in following. FIG. 2 is a flowchart of a disassembling method of the electronic device casing of FIG. 1 and FIGS. 3A-3C are diagrams showing the disassembling steps of the electronic device casing of FIG. 1. Referring to FIGS. 2 and 3A, first, a 200 is provided, which has a magnetic portion 210 (step S602). Next, referring to FIGS. 2 and 3B, the electronic device casing 100 is placed at the disassembling fixture 200 so as to withstand the elastic force of the elastic element 134 by the magnetic repulsion between the magnetic element 132 and the magnetic portion 210, such that the magnetic element 132 moves away from the first engage portion 112 (step S604). Referring to FIGS. 2 and 3C, the second shell 120 is separated from the first shell 110 (step S606) so as to finish the disassembling the electronic device casing 100.

Under the above-mentioned layout, the magnetic element 132 is pushed towards the first engage portion 112 of the first shell 110 under the elastic force of the elastic element 134 to prevent the second shell 120 from separating from the first shell 110. When the user places the electronic device casing 100 at the disassembling fixture 200 with the magnetic portion 210, the magnetic repulsion between the magnetic element 132 and the magnetic portion 210 makes the magnetic element 132 move away from the first engage portion 112 so that the second shell 120 can move away from the first shell 110. In this way, the operation of detaching the electronic device casing is more convenient.

Referring to FIG. 1, in more details, in the embodiment, the second shell 120 has a second engage portion 122. When the second shell 120 is disposed at a side of the first shell 110 and the magnetic element 132 is pushed towards the first engage portion 112 under the elastic force of the elastic element 134, and the first engage portion 112 would be deformed to lean against the second engage portion 122. The first engage portion 112 of the embodiment is, for example, a fillister and the magnetic element 132 is configured for hooking the first engage portion 112 so as to fix the first shell 110 and the second shell 120 by each other.

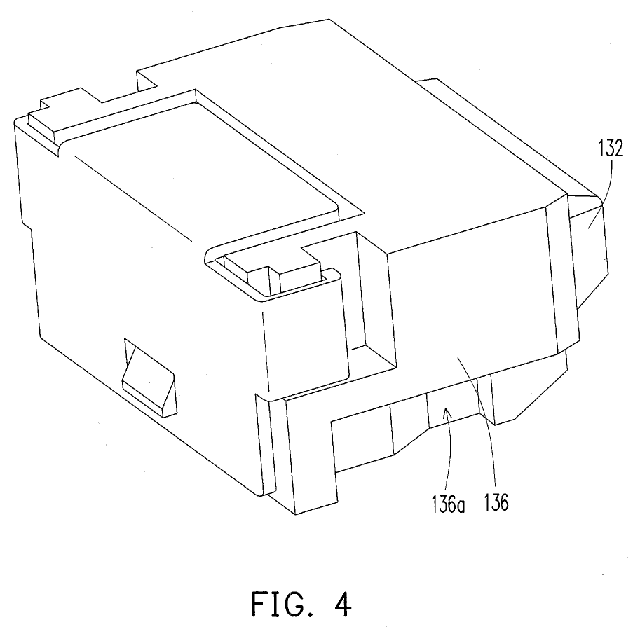

FIG. 4 is a three-dimensional diagram of partial parts of the electronic device casing of FIG. 1. Referring to FIGS. 1 and 4, the electronic device casing 100 of the embodiment further includes a base 136. The base 136 is disposed at the second shell 120 and the elastic element 134 is disposed at the base 136. In more details, the magnetic element 132 is disposed at in sliding way at the base 136 and the elastic element 134 is located between the base 136 and the magnetic element 132. In the above-mentioned step S604, when the magnetic element 132 is brought to move away from the first engage portion 112, the elastic element 134 is compressed towards the base 136 by the magnetic element 132. The base 136 and the second shell 120 can be integrally formed or separately formed, which the invention is not limited to. In addition, in the embodiment, the elastic element 134 respectively connects the base 136 and the magnetic element 132, which the invention is not limited to and the elastic element 134 is allowed not to connect the base 136 and the magnetic element 132, and at the time, through the structure design of the base 136, the elastic element can be directly disposed in the base and the magnetic element is disposed at in sliding way in the base through the structure design of the base 136 so that the elastic element still can push the magnetic element to lean against the first engage portion of the first shell.

Referring to FIG. 1, in the embodiment, the magnetic element 132 is, for example, a permanent magnet and respectively has an N-pole magnetic end 132a and a S-pole end 132b. The magnetic element 132 connects the elastic element 134 by the S-pole magnetic end 132b. In other embodiments, the magnetic element 132 can connect the elastic element 134 by the N-pole magnetic end 132a, which the invention is not limited to. In the embodiment of FIG. 1, the S-pole magnetic end 132b is, for example, a position-limiting structure, and the structure interfering between the position-limiting structure and the base 136 can avoid the magnetic element 132 from escaping the base 136.

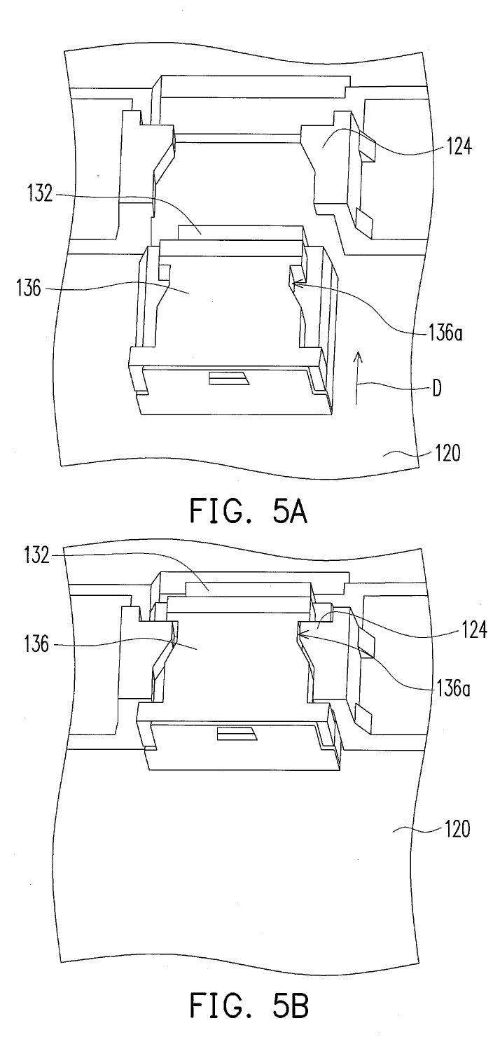

FIGS. 5A and 5B are diagrams showing the assembling step of the base and the second shell in FIG. 1. Referring to FIGS. 4 and 5A, in the embodiment, the base 136 has a locking slot 136a and the second shell 120 has a clamping structure 124. The base 136 can be installed to the second shell 120 along a direction D as shown by FIG. 5A so as to fix the base 136 at the second shell 120 through the structure interfering between the locking slot 136a and the clamping structure 124.

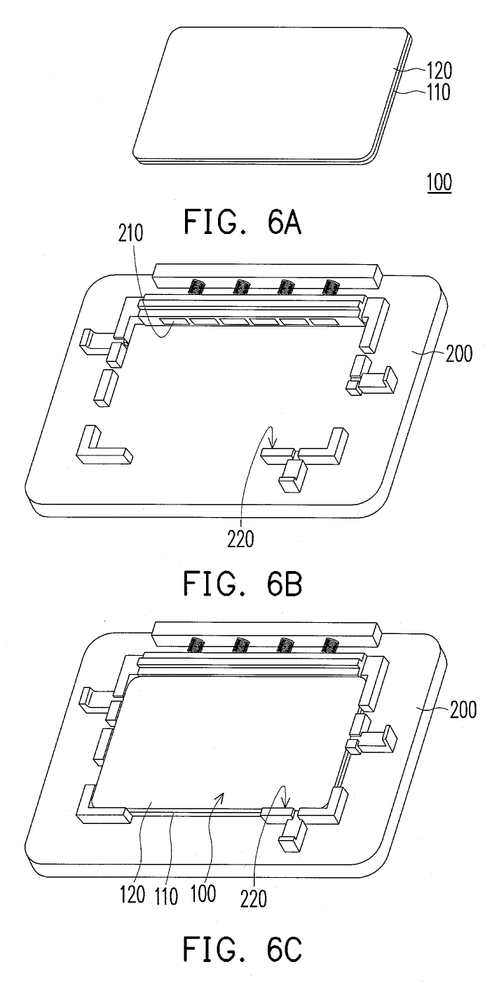

FIG. 6A is a three-dimensional diagram of the electronic device casing of the electronic device casing of FIG. 1, FIG. 6B is a three-dimensional diagram of the disassembling fixture of FIG. 3A and FIG. 6C is a three-dimensional diagram showing placing the electronic device casing of FIG. 6A at the disassembling fixture of FIG. 6B. In the embodiment, the electronic device casing 100 is, for example, a casing applied in a tablet computer and the first shell 110 and the second shell 120 are respectively the front frame and the base of the tablet computer. The disassembling fixture 200 has an accommodation basin 220 as shown in FIG. 6B, and the magnetic portion 210 is located at the accommodation basin 220. The electronic device casing 100 is configured for being fixed at the accommodation basin 220 and is corresponding to the magnetic portion 210 as shown in FIG. 6C. In other embodiments, the electronic device casing 100 can be used in other kinds of electronic devices, which the invention is not limited to.

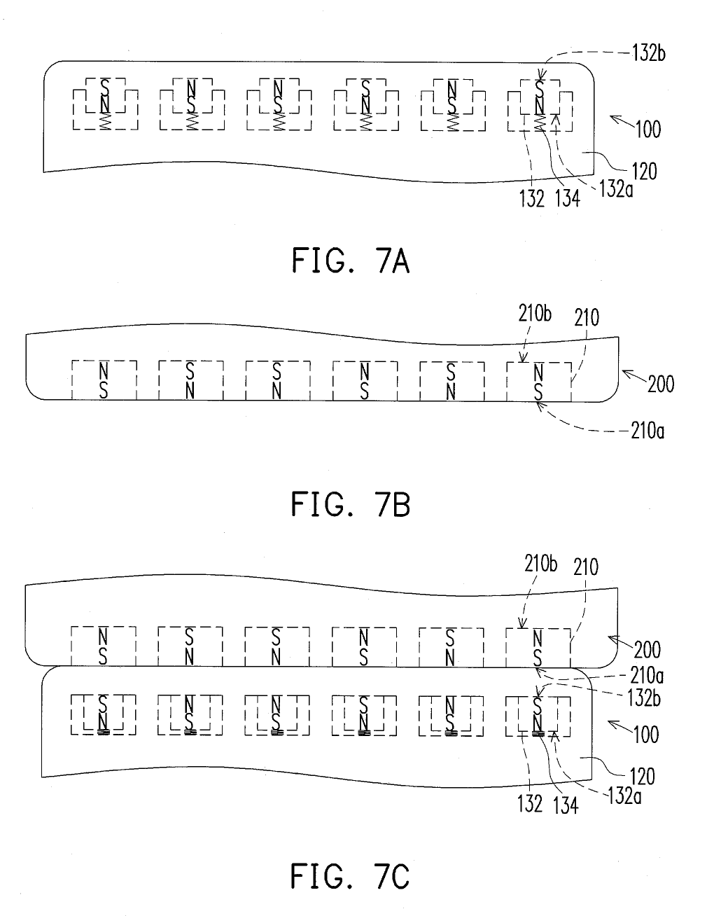

FIG. 7A is a partial top view diagram of the electronic device casing of FIG. 6A, FIG. 7B is a partial top view diagram of the disassembling fixture of FIG. 6B and FIG. 7C is a partial top view diagram of the electronic device casing and the disassembling fixture in FIG. 6C. Referring to FIGS. 7A-7C, in the embodiment, the quantity of the magnetic element 132 is plural (in figure, six ones are shown) and the quantity of the magnetic portion 210 is plural (in figure, six ones are shown). Parts of the magnetic elements 132 respectively connect the corresponding elastic elements 134 by the N-pole magnetic ends 132a, and another parts of the magnetic elements 132 respectively connect the corresponding elastic elements 134 by the S-pole magnetic ends 132b. The magnetic elements 132 are arranged in a sequence of polarities and the magnetic portions 210 are arranged in a same sequence of polarities, so that each of the magnetic elements 132 and the magnetic portions 210 opposite to the magnetic elements 132 are opposite disposed but in the same polarities. Based on the principle of the same-poles repel, there is a magnetic repulsion between each of the magnetic elements 132 and each of the magnetic portions 210. In more details, when the electronic device casing 100 is placed at the disassembling fixture 200 as shown in FIG. 7C, the S-pole magnetic ends 132b of the partial magnetic elements 132 are respectively positioned correspondingly to the S-pole magnetic ends 132b of the partial magnetic portions 210 and the N-pole magnetic ends 132a of the partial magnetic elements 132 are respectively positioned correspondingly to the N-pole magnetic ends 132a of the partial magnetic portions 210. In this way, the magnetic repulsion between each of the magnetic elements 132 and each of the corresponding magnetic portions 210 would bring the magnetic element 132 to move away from the first shell 110 as shown by FIG. 3B so as to detach the second shell 120 from the first shell 110.

In other words, under the arrangement sequence of polarities of the magnetic elements 132 as shown by FIG. 7A, the magnetic portions 210 must be arranged in the same sequence of polarities as shown by FIG. 7B to successfully bring all the magnetic elements 132 moving as shown by FIG. 7C to achieve detaching-proof effect. The invention does not limit the polarities and the arrangement sequence of polarities of the magnetic elements and the magnetic portions. In other embodiments, the polarities and the arrangement sequence of polarities of the magnetic elements and the magnetic portions can be others by appropriate design.

In summary, in the electronic device casing of the invention, the magnetic element is pushed towards the first engage portion of the first shell through the elastic force of the elastic element so as to prevent the second shell separating from the first shell. When a user places the electronic device casing at a disassembling fixture with a magnetic portion, the magnetic repulsion between the magnetic element and the magnetic portion makes the magnetic element move away from the first engage portion, such that the second shell is able to be separated from the first shell. In this way, the invention makes detaching the electronic device casing more convenient. In addition, when the magnetic elements are plural, the arrangement sequence of polarities of the magnetic elements can be defined by appropriate design, so that only the magnetic portions in a specific arrangement sequence of polarities can successfully bring all the magnetic elements to move to achieve detaching-proof effect.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. An electronic device casing, comprising:
a first shell, having a first engage portion;
a second shell, disposed at a side of the first shell;
at least one elastic element, disposed at the second shell; and
at least one magnetic element, wherein the elastic element is disposed between the magnetic element and the second shell, and the magnetic element is pushed towards the first engage portion under an elastic force of the elastic element so as to prevent the second shell separating from the first shell.

2. The electronic device casing as claimed in claim 1, wherein the magnetic element has an N-pole magnetic end and an S-pole magnetic end, and the magnetic element connects the elastic element by the N-pole magnetic end.

3. The electronic device casing as claimed in claim 1, wherein the magnetic element respectively has an N-pole magnetic end and an S-pole magnetic end, and the magnetic element connects the elastic element by the S-pole magnetic end.

4. The electronic device casing as claimed in claim 1, wherein the first engage portion is a fillister.

5. The electronic device casing as claimed in claim 1, wherein the second shell has a second engage portion, and the second engage portion and the first engage portion are leant against each other.

6. The electronic device casing as claimed in claim 1, further comprising at least one base, wherein the base is disposed at the second shell and the elastic element is disposed at the base.

7. The electronic device casing as claimed in claim 1, wherein quantity of the at least one magnetic element is plural, quantity of the at least one elastic element is plural, each of the magnetic elements has an N-pole magnetic end and an S-pole magnetic end, parts of the magnetic elements respectively connect the corresponding elastic elements by the N-pole magnetic ends, and parts of the magnetic elements respectively connect the corresponding elastic elements by the S-pole magnetic ends.

8. The electronic device casing as claimed in claim 7, wherein the magnetic elements are arranged in a sequence of polarities.

9. A disassembling method of electronic device casing, suitable for the electronic device casing claimed in claim 1 and comprising:
providing a disassembling fixture having a magnetic portion;
placing the electronic device casing at the disassembling fixture so as to withstand the elastic force of the elastic element by the magnetic repulsion between the magnetic element and the magnetic portion, such that the magnetic element moves away from the first engage portion; and
separating the second shell from the first shell.
